(19) United States
(12) Patent Application Publication
(10) Pub. No.: US 2024/0339301 A1
(43) Pub. Date: Oct. 10, 2024

(54) CCP GAS DELIVERY NOZZLE

(71) Applicant: Applied Materials, Inc., Santa Clara, CA (US)

(72) Inventors: Yogananda Sarode Vishwanath, Bangalore (IN); Andrew Nguyen, San Jose, CA (US); Tom K. Cho, Los Altos Hills, CA (US)

(21) Appl. No.: 18/206,847

(22) Filed: Jun. 7, 2023

(30) Foreign Application Priority Data
Apr. 10, 2023 (IN) 202341026631

(51) Int. Cl. H01J 37/32; B33Y 10/00; B33Y 80/00

(52) U.S. Cl. CPC H01J 37/3244; B33Y 10/00; B33Y 80/00; H01J 37/32091; H01J 37/3255; H01J 37/32568; H01J 2237/002; H01J 2237/24585; H01J 2237/334

(57) ABSTRACT

Example structures, methods, and systems for additive manufacturing of components of source and gas delivery nozzle assembly are disclosed. One example structure includes a unitary gas distribution nozzle assembly that includes an upper electrode portion and a lower electrode portion joined by multiple joining structures, and one or more gas zone divider walls positioned between the upper electrode portion and the lower electrode portion. The unitary gas distribution nozzle assembly is of a single material. Each of the multiple joining structures is positioned between the upper electrode portion and the lower electrode portion. Each of the multiple joining structures is configured to transfer radio-frequency (RF) energy and thermal energy between the upper electrode portion and the lower electrode portion. The one or more gas zone divider walls are configured to separate a region between the upper electrode portion and the lower electrode portion into two or more plenum chambers.

### CROSS-REFERENCE TO RELATED APPLICATIONS

This application claims the benefit of priority under 35 U.S.C. § 119 to Indian patent application Ser. No. 20/2341026631, filed on Apr. 10, 2023, the contents of which are hereby incorporated by reference.

### BACKGROUND

This specification relates to semiconductor systems, processes, and equipment.

Plasma etching can be used in semiconductor processing to fabricate integrated circuits. Integrated circuits can be formed from layer structures including multiple (e.g., two or more) layer compositions. Different etching gas chemistries, e.g., different mixtures of gases, can be used to form a plasma in the processing environment such that a given etching gas chemistry can have increased precision and higher selectivity for a layer composition to be etched. As scaling of integrated circuits continues to move towards smaller features and increased aspect ratios, there is a growing need for precision etching of layer structures.

### SUMMARY

Plasma processing systems include a gas delivery nozzle that distributes an etch gas mixture into a plasma processing chamber. This etch gas mixture is ignited using a plasma source to generate a plasma. Charged particles of the plasma are drawn towards an exposed surface of a substrate retained in the processing region of the chamber to perform an etching process on the exposed surface of the substrate.

The plasma is formed using a particular plasma source. One type of plasma source is a capacitively coupled plasma (“CCP”) source. The CCP plasma source supplies radio frequency energy to an electrode at the top of the plasma chamber that acts as a first parallel plate of a capacitor. The electrode can include the gas delivery nozzle.

The gas delivery nozzle, also referred to as a showerhead, is typically manufactured by assembling multiple components. Specifically, the gas delivery nozzle for a typical CCP source can include three separate structures press-fitted together and configured to provide thermal conductivity characteristics. The three separate structures include an upper electrode plate, a lower electrode plate, and multiple pins connecting these two plates. The gas delivery nozzle can include separate regions for receiving etch gases. The gas delivery nozzle can include a top gas divider O-ring and a bottom gas divider O-ring to separate these regions. The O-rings can be of a different material than the electrode plates and connecting pins. The top gas divider O-ring and a bottom gas divider O-ring can be mounted between the two plates and are not in thermal contact with the two plates. The material mismatch between pins of the same material and O-rings of a different material can lead to thermal non-uniformity in heat transfer between portions of the gas delivery nozzle.

The present specification describes technologies for gas delivery nozzles and adjacent assemblies used in a plasma processing system. These technologies generally involve using additive manufacturing techniques to design and fabricate gas delivery nozzles, which can also be referred to as “showerheads,” for use in plasma processing systems. In particular, a unitary gas delivery nozzle is provided that uses additive manufacturing to combine the upper and lower electrode plates, joining structures, and one or more gas divider wall into a single component. In particular, by fabricating the one or more gas divider walls as part of the gas delivery nozzle structure, the need for gas sealing O-rings is eliminated. The present specification further describes using additive manufacturing to integrate the gas delivery nozzle with one or more additional components of the plasma processing system including a cooling plate and gas block.

Certain aspects of the subject matter described in this specification can be implemented as a structure embodied in a machine readable medium used in a design process. The structure includes a unitary gas distribution nozzle assembly that includes an upper electrode portion, a lower electrode portion, multiple joining structures that join the lower electrode portion and the upper electrode portion, and one or more gas zone divider walls. The upper electrode portion, the lower electrode portion, the plurality of joining structures, and the one or more gas zone divider walls are of a same material. Each of the multiple joining structures is positioned between and coupled to the upper electrode portion and the lower electrode portion. Each of the multiple joining structures is configured to transfer RF energy and thermal energy between the upper electrode portion and the lower electrode portion. The one or more gas zone divider walls are positioned between and coupled to the upper electrode portion and the lower electrode portion. The one or more gas zone divider walls are configured to separate a region between the upper electrode portion and the lower electrode portion into two or more plenum chambers.

The structure can include one or more of the following features.

In some implementations, the structure resides on storage medium as a data format used for an exchange of layout data.

In some implementations, the structure includes at least one of test data files, characterization data, verification data, or design specifications.

In some implementations, the one or more gas zone divider walls are annular walls that demarcate at least an inner plenum chamber and an outer plenum chamber within the region between the upper electrode portion and the lower electrode portion.

In some implementations, the unitary gas distribution nozzle assembly further includes a cooling portion positioned above and coupled to the upper electrode portion, where the cooling portion is configured to provide cooling to the upper electrode portion.

In some implementations, the unitary gas distribution nozzle assembly further includes an embedded sensor to measure a flow rate of a coolant fluid circulating the cooling portion, and the coolant fluid circulates from a chiller and to the cooling portion to provide cooling to the upper electrode portion.

In some implementations, the unitary gas distribution nozzle assembly further includes a radio-frequency block portion positioned above and coupled to the cooling portion, and the radio-frequency block portion couples RF energy to gas in the two or more plenum chambers.

In some implementations, the unitary gas distribution nozzle assembly further includes one or more sensors embedded in one or more of the multiple joining structures.

Certain aspects of the subject matter described here can be implemented as a plasma processing system. The plasma processing system includes a unitary gas distribution nozzle assembly that includes an upper electrode portion, a lower electrode portion, multiple joining structures that join the lower electrode portion and the upper electrode portion, and one or more gas zone divider walls. The upper electrode portion, the lower electrode portion, the plurality of joining structures, and the one or more gas zone divider walls are of a same material. Each of the multiple joining structures is positioned between and coupled to the upper electrode portion and the lower electrode portion. Each of the multiple joining structures is configured to transfer RF energy and thermal energy between the upper electrode portion and the lower electrode portion. The one or more gas zone divider walls are positioned between and coupled to the upper electrode portion and the lower electrode portion. The one or more gas zone divider walls are configured to separate a region between the upper electrode portion and the lower electrode portion into two or more plenum chambers.

The structure can include one or more of the following features.

In some implementations, the unitary gas distribution nozzle assembly further includes a cooling portion positioned above and coupled to the upper electrode portion, where the cooling portion is configured to provide cooling to the upper electrode portion.

In some implementations, the unitary gas distribution nozzle assembly further includes an embedded sensor to measure a flow rate of a coolant fluid circulating the cooling portion, and the coolant fluid circulates from a chiller and to the cooling portion to provide cooling to the upper electrode portion.

In some implementations, the unitary gas distribution nozzle assembly further includes one or more sensors embedded in one or more of the multiple joining structures.

Certain aspects of the subject matter described here can be implemented as a method. The method includes additively manufacturing a unitary gas distribution nozzle assembly. Additively manufacturing the unitary gas distribution nozzle assembly includes forming multiple layers including a lower electrode portion. Multiple layers including multiple joining structures that are coupled to the lower electrode portion are formed. Multiple layers including one or more gas zone divider walls that are coupled to the lower electrode portion are formed. Multiple layers including an upper electrode portion that is coupled to the multiple joining structures and the one or more gas zone divider walls are formed. The upper electrode portion, the lower electrode portion, the plurality of joining structures, and the one or more gas zone divider walls are of a same material. Each of the multiple joining structures is positioned between and coupled to the upper electrode portion and the lower electrode portion. Each of the multiple joining structures is configured to transfer RF energy and thermal energy between the upper electrode portion and the lower electrode portion. The one or more gas zone divider walls are positioned between and coupled to the upper electrode portion and the lower electrode portion. The one or more gas zone divider walls are configured to separate a region between the upper electrode portion and the lower electrode portion into two or more plenum chambers.

The method can include one or more of the following features.

In some implementations, additively manufacturing the unitary gas distribution nozzle assembly further includes forming multiple layers including a cooling portion positioned above and coupled to the upper electrode portion, where the cooling portion is configured to provide cooling to the upper electrode portion.

In some implementations, the unitary gas distribution nozzle assembly further includes an embedded sensor to measure a flow rate of a coolant fluid circulating the cooling portion, and where the coolant fluid circulates from a chiller and to the cooling portion to provide cooling to the upper electrode portion.

In some implementations, the unitary gas distribution nozzle assembly further includes one or more sensors embedded in one or more of the plurality of joining structures.

The subject matter described in this specification can be implemented in these and other embodiments so as to realize one or more of the following advantages. An additively manufactured gas delivery nozzle can retain the functions and performance of a gas delivery nozzle having individually manufactured parts. The additively manufactured gas delivery nozzle can also provide improved thermal conductivity characteristics by eliminating gas divider O-rings made from a different material than the rest of the gas delivery nozzle. A top gas divider O-ring and a bottom gas divider O-ring in a gas delivery nozzle with individually manufactured parts can be replaced with a gas divider wall that is of the same material as other portions of the additively manufactured gas delivery nozzle, e.g., an aluminum alloy or other conductive material, and therefore reducing thermal non-uniformity associated with the top and bottom gas divider O-rings. By forming the gas delivery nozzle from additive manufacturing, alignment issues in assembly can be reduced. Additionally, the additively manufactured gas delivery nozzle can eliminate e-beam as well as leak checks, reduce cost associated with machining waste, handle complex geometry, and shorten turn-around time and manufacturing steps. Furthermore, additive manufacturing can be used to generate an entire source and gas delivery nozzle assembly including combining the gas delivery nozzle, chill plate, and optionally an RF block as a single resulting component. This can simplify assembly, reduce alignment problems, and eliminate the need for various gas seals, e.g., O-rings, to deliver etch gases to the gas delivery nozzle.

Although the remaining disclosure will identify specific additively manufactured structures using the disclosed technology, it will be readily understood that the structures are equally applicable to a variety of other structures as can occur in the described source showerhead electrode assembly. Accordingly, the technology should not be considered to be so limited as for use with the described structures alone. The disclosure will discuss one possible structure that can be used with the present technology before describing structures according to some embodiments of the present technology. It is to be understood that the technology is not limited to the structures described, and structures discussed can be used in any number of source showerhead electrode assemblies.

### BRIEF DESCRIPTION OF DRAWINGS

FIG. 1 illustrates an example of a schematic cross-sectional view of a plasma processing chamber.

FIG. 2 illustrates a cross-sectional view of an example source and gas delivery nozzle assembly for a capacitively coupled plasma source.

FIG. 3 illustrates a cross-sectional view of an example gas delivery nozzle.

FIG. 4 illustrates a top view of an example gas delivery nozzle without an upper electrode plate.

FIG. 5 illustrates a top view of another example gas delivery nozzle without an upper electrode plate.

FIG. 6A illustrates example cross-section shapes of a joining structure in a gas delivery nozzle.

FIG. 6B illustrates an example structure of a gas delivery nozzle that uses a cross-section shape in FIG. 6A for joining structures that connect an upper electrode plate and a lower electrode plate.

FIG. 7 illustrates a cross-sectional view of an example additively manufactured source and gas delivery nozzle assembly together with a chiller.

FIG. 8 illustrates a flow diagram of an example process for manufacturing a unitary gas distribution nozzle assembly

FIG. 9 is a schematic illustration of an example computing system that can be used to execute implementations of the present disclosure.

Like reference numbers and designations in the various drawings indicate like elements.

### DETAILED DESCRIPTION

This specification relates to structures, methods, and systems for additively manufactured components of a source and gas delivery nozzle assembly for capacitively coupled plasma source. An additively manufactured gas delivery nozzle can retain the functions and performance of a gas delivery nozzle with individually manufactured components. The additively manufactured gas delivery nozzle can also provide superior thermal conductivity characteristics as compared to a gas delivery nozzle with individually manufactured components. A top gas divider O-ring and a bottom gas divider O-ring in a gas delivery nozzle with individually manufactured parts is replaced with a gas divider wall that is of the same material as other portions of the additively manufactured gas delivery nozzle, and therefore reducing thermal non-uniformity associated with the top and bottom gas divider O-rings. Additionally, additively manufactured gas delivery nozzles can eliminate e-beam as well as leak checks, reduce cost associated with machining waste, handle complex geometry, and shorten turn-around time and manufacturing steps.

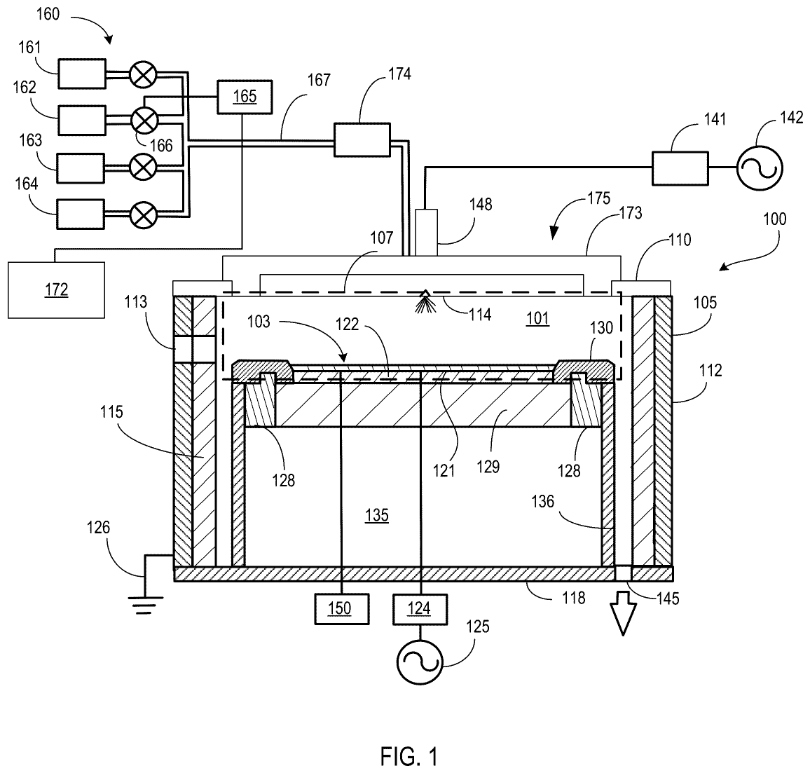

FIG. 1 illustrates an example 100 of a schematic cross-sectional view of a plasma processing chamber suitable for etching one or more material layer(s) disposed on a substrate 103 (e.g., also referred to as a “wafer”) in the processing chamber 100, e.g., a plasma processing chamber. The processing chamber 100 includes a chamber body 105 defining a chamber volume 101 in which a substrate can be processed. The chamber body 105 has sidewalls 112 and a bottom 118 which are coupled with ground 126. The sidewalls 112 can include a liner 115 to protect the sidewalls 112 and extend the time between maintenance cycles of the plasma processing chamber 100. The chamber body 105 is supportive of a chamber lid assembly 110 to enclose the chamber volume 101. The chamber body 105 can be fabricated from, for example, aluminum or other suitable materials. A substrate access port 113 is formed through the sidewall 112 of the chamber body 105, which can facilitate the transfer of the substrate 103 into and out of the plasma processing chamber 100. Access port 113 can be coupled with a transfer chamber and/or other chambers (not shown) of a substrate processing system, e.g., to perform other processes on the substrate. A pumping port 145 is formed through the bottom 118 of the chamber body 105 and connected to the chamber volume 101. A pumping device can be coupled through the pumping port 145 to the chamber volume 101 to evacuate and control the pressure within the processing volume. The pumping device can include one or more pumps and throttle valves.

Chamber volume 101 includes a processing region 107, e.g., a station for processing a substrate. A substrate support 135 can be disposed in the processing region 107 of chamber volume 101 to support the substrate 103 during processing. The substrate support 135 can include an electrostatic chuck 122 for holding the substrate 103 during processing. The electrostatic chuck (“ESC”) 122 can use the electrostatic attraction to hold the substrate 103 to the substrate support 135. The ESC 122 can be powered by a radio-frequency (RF) power supply 125 integrated with a match circuit 124. The ESC 122 can include an electrode 121 embedded within a dielectric body. The electrode 121 can be coupled with the RF power supply 125 and can provide a bias which attracts plasma ions, formed from the process gases in the chamber volume 101, to the ESC 122 and substrate 103 seated on the pedestal. The RF power supply 125 can cycle on and off, or pulse, during processing of the substrate 103. The ESC 122 can have an isolator 128 for the purpose of making the sidewall of the ESC 122 less attractive to the plasma to prolong the maintenance life cycle of the ESC 122. Additionally, the substrate support 135 can have a cathode liner 136 to protect the sidewalls of the substrate support 135 from the plasma gases and to extend the time between maintenance of the plasma processing chamber 100.

Electrode 121 can be coupled with a DC power source 150. The power source 150 can provide a chucking voltage of about 200 volts to about 2000 volts to the electrode 121. The power source 150 can also include a system controller for controlling the operation of the electrode 121 by directing a DC current to the electrode 121 for chucking and de-chucking the substrate 103. The ESC 122 can include heaters disposed within the and connected to a power source for heating the substrate, while a cooling base 129 supporting the ESC 122 can include conduits for circulating a heat transfer fluid to maintain a temperature of the ESC 122 and substrate 103 disposed thereon. The ESC 122 can be configured to perform in the temperature range required by the thermal budget of the device being fabricated on the substrate 103. For example, the ESC 122 can be configured to maintain the substrate 103 at a temperature of about −150° C. or lower to about 500° C. or higher depending on the process being performed. A cover ring 130 can be disposed on the ESC 122 and along the periphery of the substrate support 135. The cover ring 130 can be configured to confine etching gases to a desired portion of the exposed top surface of the substrate 103, while shielding the top surface of the substrate support 135 from the plasma environment inside the plasma processing chamber 100.

A gas panel 160 (e.g., also referred to herein as “gas distribution manifold”) can be coupled by a gas line 167 with the chamber body 105 through chamber lid assembly 110 to supply process gases into the chamber volume 101. The gas panel 160 can include one or more process gas sources 161, 162, 163, 164 and can additionally include inert gases, non-reactive gases, and reactive gases, as can be used for any number of suitable processes. Examples of process gases that can be provided by the gas panel 160 include, but are not limited to, hydrocarbon containing gases including methane, sulfur hexafluoride, silicon chloride, silicon tetrachloride, carbon tetrafluoride, hydrogen bromide. Process gases that can be provided by the gas panel can include, but are limited to, argon gas, chlorine gas, nitrogen, helium, or oxygen gas, sulfur dioxide, as well as any number of additional materials. Additionally, process gasses can include nitrogen, chlorine, fluorine, oxygen, or hydrogen containing gases including, for example, BCl3, C2F4, C4F8, C4F6, CHF3, CH2F2, CH3F, NF3, NH3, CO2, SO2, CO, N2, NO2, N2O, and H2, among any number of additional suitable precursors. Process gases from process gas sources, e.g., sources 161, 162, 163, 164, can be combined to form one or more etching gas mixtures. For example, gas panel 160 includes one or more process gas sources specific to oxide-based etching chemistries. In another example, gas panel 160 includes one or more process gas sources specific to nitride-based etching chemistries.

Gas panel 160 includes various valves, pressure regulators (not shown), and mass flow controllers (not shown) arranged with respect to the gas sources 161, 162, 163, 164 to control the flow of the process gases from the sources. Valves 166 can control the flow of the process gases from the sources 161, 162, 163, 164 from the gas panel 160. Operations of the valves, pressure regulators, and/or mass flow controllers can be controlled by a controller 165. Controller 165 can be operably coupled to an electro-valve (EV) manifold (not shown) to control actuation of one or more of the valves, pressure regulators, and/or mass flow controllers.

A gas delivery assembly 175 is coupled to the lid 110. The gas delivery assembly 175 includes a gas delivery nozzle 114 and a chill plate 173. The chill plate 173 provides thermal transfer from the gas delivery nozzle 114, which is exposed to the heat of the plasma processing chamber 100. The chill plate 173 includes pathways for passing process gases, e.g., from gas line 167, to the gas delivery nozzle 114. The gas delivery nozzle 114 can include one or more openings for introducing the process gases from the sources 161, 162, 163, 164 of the gas panel 160 into the chamber volume 101.

After the process gases are introduced into the plasma processing chamber 100, the gases can be energized to form a plasma. Different sources can be used to couple energy, such as RF energy, to the process gases to form and maintain a plasma in the chamber volume 101 of the plasma processing chamber 100. Example sources include a capacitively coupled plasma (“CCP”) source and an inductively coupled plasma (“ICP”) source. A CCP source includes an electrode block 148 adjacent to the plasma processing chamber 100. The electrode can further be coupled to the gas delivery nozzle 114, e.g., through the chill plate 173. When charged, the gas delivery nozzle 114 forms a first parallel plate of a capacitor having a second electrode, e.g., electrode 121 in the ESC 122. A power supply 142 can power the electrode block 148 and gas delivery nozzle 114 through a match circuit 141 to capacitively couple energy to the process gas. The operation of the power supply 142 can be controlled by a controller, such as controller 165, that also controls the operation of other components in the plasma processing chamber 100.

The controller 165 can be used to control the process sequence, regulating the gas flows from the gas panel 160 into the plasma processing chamber 100, and other process parameters. Software routines, when executed by a computing device having one or more processors (e.g., a central processing unit (CPU)) in data communication with one or more memory storage devices, transform the computing device into a specific purpose computer such as a controller, which can control the plasma processing chamber 100 such that the processes are performed in accordance with the present disclosure. The software routines can also be stored and/or executed by one or more other controller(s) that can be associated with the plasma processing chamber 100.

In some implementations, at a termination point of etching process(es) for the wafer, an automatic or semi-automatic robotic manipulator (not shown) can be utilized to transfer the wafer(s) from the substrate support out of the process chamber, e.g., through substrate access port 113. For example, the robotic manipulator can transfer the wafer to another chamber (or another location) to perform another step in a fabrication process.

Although described with respect to FIG. 1 as a process chamber including a substrate support disposed within a processing region of the chamber volume, two or more substrate supports can be disposed within the same chamber volume in respective processing regions, e.g., in respective processing stations. For example, a processing chamber 100 can be a tandem processing chamber including two processing regions each with respective substrate supports configured to retain respective wafers during etching process(es). The processing chamber 100 can include two or more processing regions within the chamber volume 101 to facilitate parallel processing of two or more substrates in respective processing regions. The processing regions can be substantially isolated such that an etching process in a first processing region has minimal effect on an etching process in a second processing region and vice-versa.

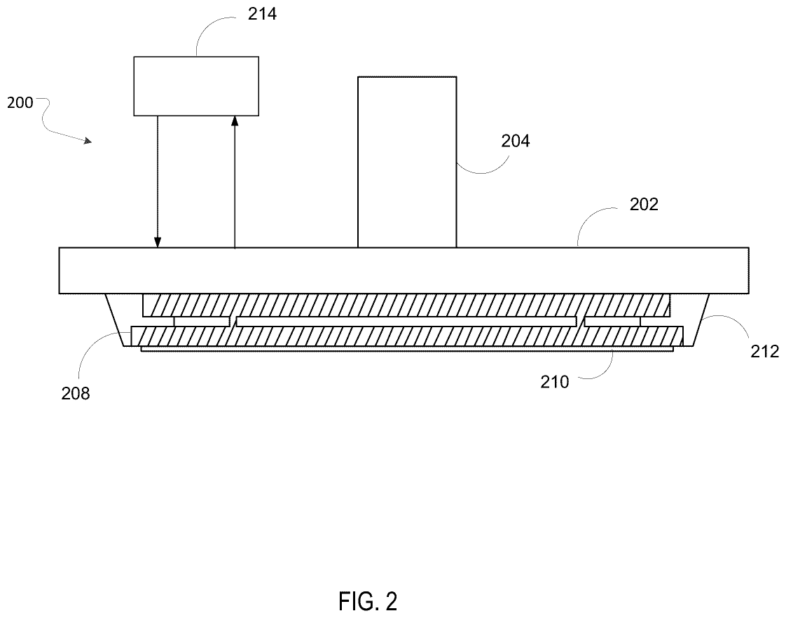

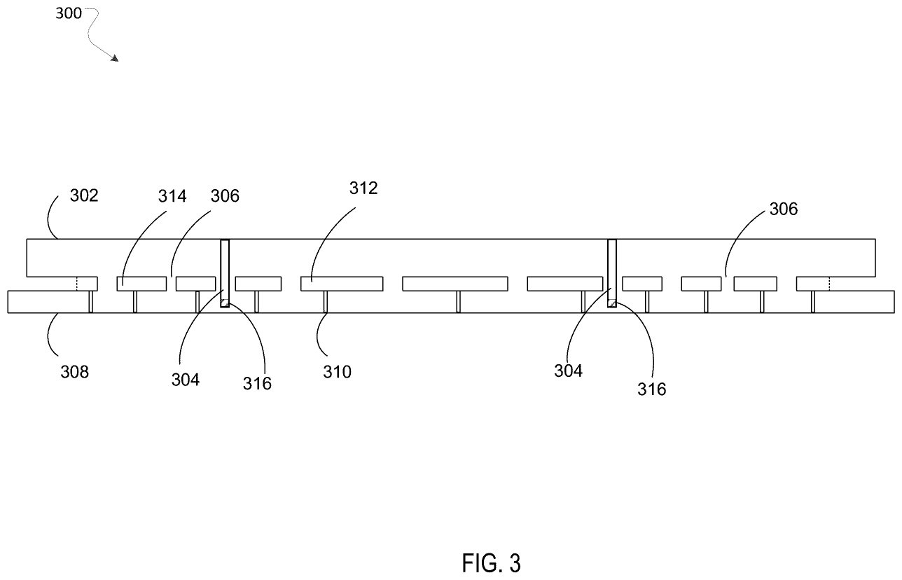

FIG. 2 illustrates a cross-sectional view of an example of a source and gas delivery nozzle assembly 200 for a capacitively coupled plasma source. In some implementations, RF block 204 can be an embodiment of RF block 148 in FIG. 1. The source and gas delivery nozzle assembly 200 also includes a chill plate 202, gas delivery nozzle 208, insulating rings 212, gas distribution plate 210, and a chiller 214 that is coupled to chill plate 202. The chiller 214 is used to circulate a coolant fluid through the chill plate 202 to achieve a specified temperature. The gas delivery nozzle 208 can be an embodiment of gas delivery nozzle 114 in FIG. 1. The gas delivery nozzle 208 includes an upper portion and a lower portion at least partially enclosing one or more plenums, as will be described in greater detail below with respect to FIG. 3. The gas delivery nozzle 208 can be fabricated as a single structure using, for example, additive manufacturing techniques. Insulating rings 212 can seal a portion of a plenum of the gas delivery nozzle at an edge as well as provide an insulating barrier between the electrically charged gas delivery nozzle 208 and a chamber lid, e.g., chamber lid assembly 110 of FIG. 1.

Chill plate 202 can be used as a heat exchanger to provide cooling for the gas delivery nozzle, and input etch gases, to counteract heat generated by plasma in the processing chamber. Gas distribution plate (GDP) 210 can be bound to the gas delivery nozzle 208. For example, the gas distribution plate 210 can have openings that align with gas output holes in the gas delivery nozzle 208. The gas distribution plate 210 can be formed from a material that provides protection to the gas delivery nozzle 208 from the plasma in the processing chamber. In some implementations, the gas distribution plate 210 is formed from a material such as ceramic, yttria, silicon carbide, silicon or equivalent. When the RF block 204 is powered by a power supply (e.g., power supply 142 of FIG. 1), energy is conducted to the gas delivery nozzle 208, which becomes electrically charged. The energy can be conducted through a conductive chill plate, or through one or more electrode structures passing through the chill plate to the gas delivery nozzle.

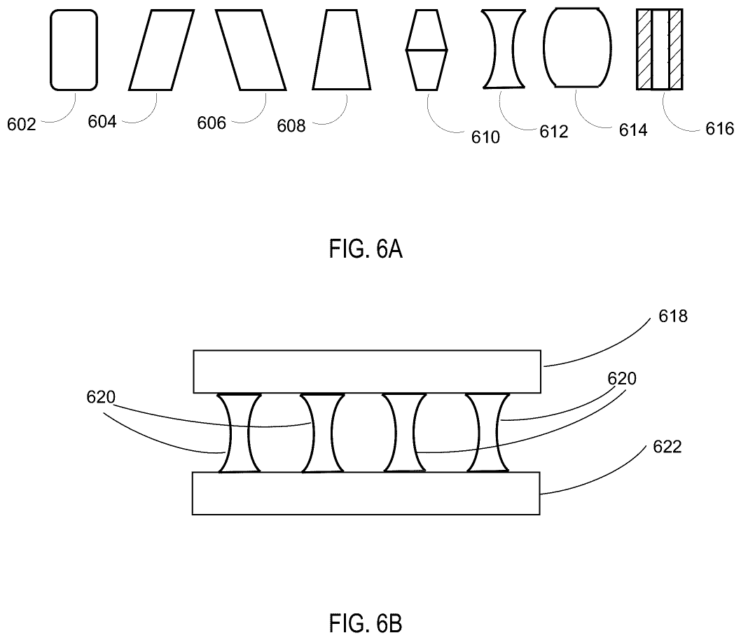

FIG. 3 illustrates a cross-sectional view of an example gas delivery nozzle 300. The gas delivery nozzle 300 can be an embodiment of gas delivery nozzle 208 in FIG. 2. The gas delivery nozzle 300 includes upper electrode plate 302 and lower electrode plate 308 that are joined together at several points by joining structures 304. In some implementations, joining structures 304 can transfer both thermal energy and RF energy between upper electrode plate 302 and lower electrode plate 308. The total number of joining structures 304 can be determined such that a balance between thermal energy transfer and RF energy transfer is achieved. In one example, the total number of joining structures 304 is 79. An example material for upper electrode plate 302, lower electrode plate 308, and joining structures 304 is a suitable aluminum alloy such as aluminum 6061-T6. The joining structure 304 are formed together with the upper electrode plate 302 and lower electrode plate 308, for example, through additive manufacturing. Thus, the joining structures 304 are not separate components, but part of a unitary gas delivery nozzle body. In some implementations, example shapes of the joining structures 304 can include cylindrical, angled, trapezoidal, hourglass, or rectangular peg shape, each of which can have its own strength characteristics. FIG. 6A illustrates example cross-section shapes 602 to 616 of joining structure 304. FIG. 6B illustrates an example structure of gas delivery nozzle 300 that uses cross-section shape 612 in FIG. 6A for joining structures 620 that connect upper electrode plate 618 and lower electrode plate 622.

In some implementations, one or more plenum chambers can be formed between upper electrode plate 302 and lower electrode plate 308. In particular, as shown in FIG. 3, the gas delivery nozzle 300 includes a first plenum chamber 312 and a second plenum chamber 314. The two plenum chambers can be formed using a gas divider wall 306. The gas divider wall 306 provides a gas seal between the first plenum chamber 312 and the second plenum chamber 314. In some implementations, the gas divider wall 306 can be an annular wall. By fabricating the joining structures 304 and gas divider wall 306 from the same material as the upper electrode plate 302 and lower electrode plate 308, both the joining structures and gas divider wall provide uniform thermal transfer, e.g. from the lower electrode plate 308 to the upper electrode plate 302.

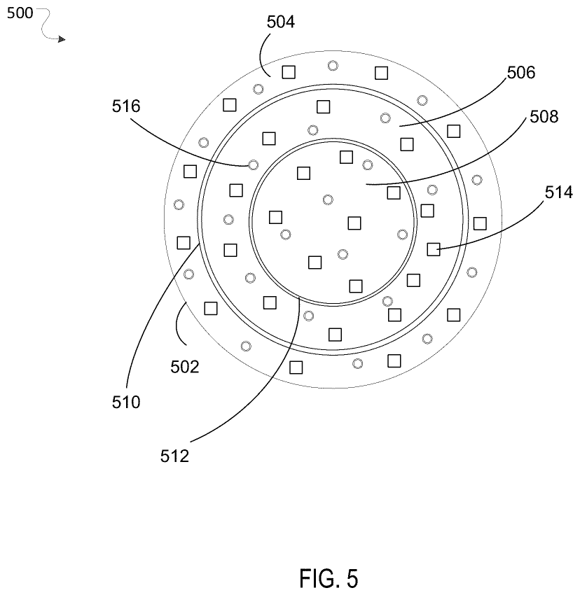

In some implementations, additional divider walls can be used to form more than two plenum chambers, for example, three plenum chambers (e.g., inner, middle, and outer plenum chambers) or four plenum chambers. Additional plenum chambers can achieve improved gas flow control and process uniformity to get desired etch rates across wafer. For example, lower nodes device applications may need tighter control and additional knobs to tune the performance. An example of a gas delivery nozzle with three plenum chambers 504, 506, and 508 that are formed using two gas divider walls 510 and 512 is shown in FIG. 5.

The lower electrode plate 308 includes multiple gas output holes 310 to discharge gas from the gas delivery nozzle 300, e.g., into a processing chamber. The upper electrode plate 302 also includes two or more gas paths allowing etch cases to be input into the first plenum chamber 312 and the second plenum chamber 314. Each plenum chamber allows for input etch gasses to evenly distribute within the plenum such that the etch gases flow out of the output gas holes coupled to the plenum at the same rate. Thus, the plenum chambers help provide for an even distribution of etch gases into a particular region of the processing chamber.

In some implementations, for designs with multiple plenum chambers, for example, four or more plenum chambers, gas lines can connect to these plenum chambers independently, and flow ratio controllers (FRCs) can be used to proportionately divide the gas flow in the ratio necessary based on process application needs and provided to the plenum chambers. Each plenum gas delivery can also have RF gas break to isolate RF electrode with ground.

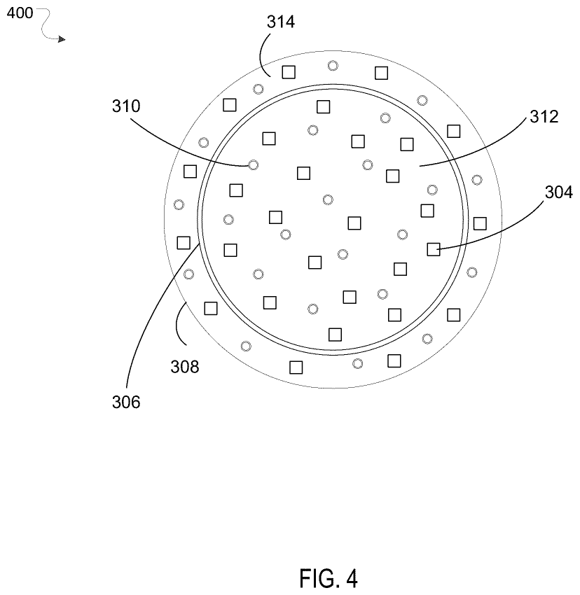

FIG. 4 illustrates a top view 400 of the example gas delivery nozzle 300 without upper electrode plate 302. In particular, FIG. 4 illustrates the lower electrode plate 308, gas divider wall 306, joining structure 304, and gas output holes 310. The gas divider wall 306 is a circular ring that separates the first plenum chamber 312 from the second plenum chamber 314. Joining structures 304 are dispersed within both the first plenum chamber 312 and second plenum chamber 314. In some implementations, the gas divider wall 306 can have other shapes, depending on the shape of the wafer and the number of plenum chambers.

With the upper electrode plate 302 and lower electrode plate 308, the gas divider wall 306 forms a barrier between the first plenum chamber 312 from the second plenum chamber 314. For example, a first gas line can supply etch gases to the first plenum chamber 312 through a first opening in the upper electrode plate 302. A second gas line can supply etch gases to the second plenum chamber 314 through a second opening in the upper electrode plate 302. The etch gases and gas pressures can be independently controlled for each gas line. As a result, the pressure and composition of etch gases within each plenum chamber can be independent. The independent control allows for more control over etch processes.

For example, the first plenum chamber 312 can include gas output holes 310 that direct the etch gases to a portion of the chamber so that, when the etch gases are ionized into a plasma, charged particles are directed to a central region of a substrate. Similarly, the second plenum chamber 314 can include gas output holes 310 that direct the etch gases to a portion of the chamber so that, when the etch gases are ionized into a plasma, charged particles are directed to an edge region of the substrate. The rate of etching may be different between the center region and edge region of the substrate. Independent plenum chambers for independently supplying etch gases can help provide for control of the etch rates to ensure consistent etching across the substrate.

Although FIGS. 3-4 provide an example gas delivery nozzle with two plenum chambers, other variations are possible. For example, two gas divider walls can be formed to create three plenum chambers, e.g., inner, middle, and edge plenum chambers. Each of these three plenum chambers can be independently supplied with etch gases for delivery into the processing chamber. FIG. 5 illustrates a top view 500 of another example gas delivery nozzle without an upper electrode plate. In particular FIG. 5 shows a lower electrode plate 502 and three plenum chambers 504, 506, and 508 that are formed using two gas divider walls 510 and 512.

Additionally, as shown in FIG. 3, an outer gas seal for the second plenum chamber 314 is provided by a separate component from the gas delivery nozzle 300, e.g., the insulating rings 212 showing in FIG. 2. However, in other implementations, a separate gas divider wall can be formed as part of the gas delivery nozzle 300 to demarcate the boundaries of the second plenum chamber 314. In some implementations, one or more sensors can optionally be embedded into joining structures (e.g., pins). These joining structures with sensors can be added during an additive manufacturing process to fabricate the gas delivery nozzle, e.g., the sensors can be directly 3D printed. Example sensors can include thermocouples to measure the temperature of showerhead at multiple places. Benefits of having 3D printed joining structures with sensors can include close loop temperature monitoring and heat exchange, improved thermal profile of the showerhead, and avoiding hot/cold spots and by-products adhesion. FIG. 3 shows example sensors 316 embedded within joining structures 304.

As described above, the gas delivery nozzle 300 can be fabricated using additive manufacturing techniques. This allows for the formation of the gas delivery nozzle 300 as a single structure that eliminates the need for alignment pins for joining the upper and lower electrode as well as the need for gas sealing O-rings that cause non-uniform thermal transfer. For use in a CCP system, the gas delivery nozzle 300 is fabricated from a conductive material, for example, an aluminum alloy such as aluminum 6061-T6. Other materials can also be used, for example, aluminum alloy or equivalent in powder format for 3D printing, such as AlSi10Mg, Al6061 RAM2, or metal matrix materials. Other high thermal conductive and electrically conductive and corrosive resistant, high strength metals can also be used. In some implementations, the entire structure is formed using additive manufacturing, e.g., including gas flow paths and output gas holes. In some other implementations, the additive manufacturing is augmented by subsequent manufacturing processes. For example, the lower electrode plate can be additively manufactured with a solid surface that is then processed to add output gas holes, e.g., by laser drilling.

In some implementations, 3D printed electrode can be used to bond the gas distribution plate made of ceramic material to minimize erosion and metal contamination due to exposure to plasma. Example GDP materials can include Silicon, bulk Yttria, Silicon Carbide, or other equivalents. In some implementations, the GDP can also be 3D printed directly to metal electrode assembly described above to form a single part as a showerhead.

In some implementations, a computer aided design (CAD) model of the gas delivery nozzle is first made and then a slicing algorithm maps the information for every layer. A layer starts off with a thin distribution of powder spread over the surface of a powder bed. A chosen binder material then selectively joins particles where the gas delivery nozzle is to be formed. Then a piston which supports the powder bed and the part-in-progress is lowered in order for the next powder layer to be formed. After each layer, the same process is repeated followed by a final heat treatment to make the gas delivery nozzle. Since 3-D printing can exercise local control over the material composition, microstructure, and surface texture, various (and previously inaccessible) geometries may be achieved with this method.

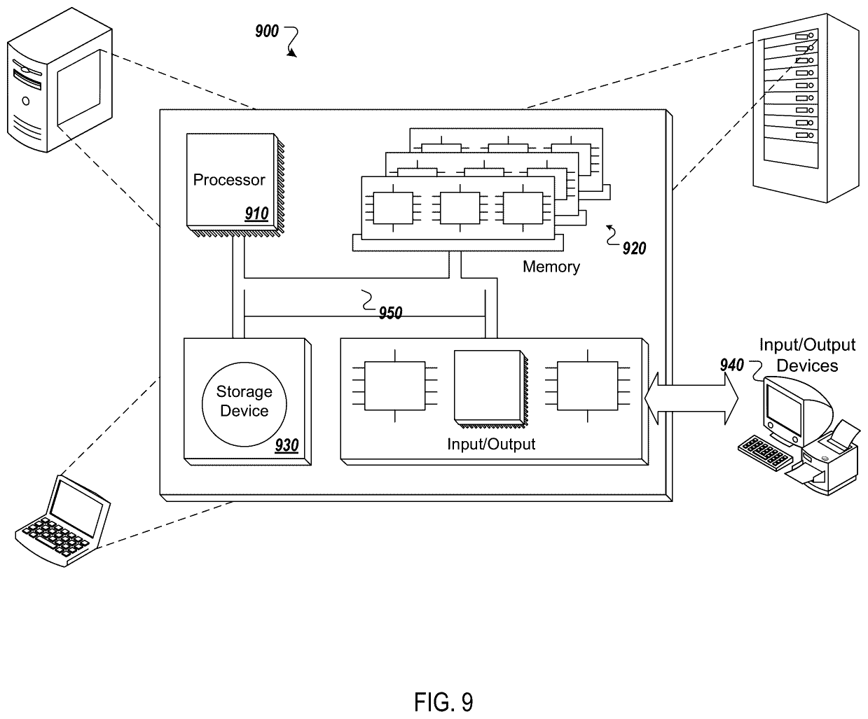

In some implementations, the gas delivery nozzle as described in this specification may be represented in a data structure readable by a computer rendering device or a computer display device. FIG. 9 is a schematic illustration of an example computing system 900 that can be used to execute implementations of the present disclosure. In some implementations, memory 920 is a computer-readable medium that may contain a data structure that represents the gas delivery nozzle. The data structure may be a computer file, and may contain information about the structures, materials, textures, physical properties, or other characteristics of one or more articles. The data structure may also contain code, such as computer executable code or device control code that engages selected functionality of a computer rendering device or a computer display device. The data structure may be stored on the computer-readable medium. The computer readable medium may include a physical storage medium such as a magnetic memory, floppy disk, or any convenient physical storage medium. The physical storage medium may be readable by the example computing system 900 to render the gas delivery nozzle represented by the data structure on a computer screen or a physical rendering device which may be an additive manufacturing device, such as a 3-D printer.

In some implementations, additive manufacturing of a gas delivery nozzle can avoid variations in manufacturing individual parts of a gas delivery nozzle, as well as machining wastage, handling, and tooling associated with manufacturing individual parts of the gas delivery nozzle. Using additive manufacturing also allows for non-conductive O-rings to be replaced with a gas zone divider wall that, unlike O-rings, can be formed from the same material as the rest of the gas delivery nozzle, thus improving the uniformity in heat transfer between lower and upper electrode plates.

In some implementations, additive manufacturing of the gas delivery nozzle can eliminate assembly mismatch and press-fit issues, as well as e-beam and leak checks, associated with individually manufactured parts of the gas delivery nozzle. It can also improve repeatability and chamber matching between processing chambers or processing regions of a tandem processing chamber.

In some implementations, the total number of joining structures in an additively manufactured gas delivery nozzle, as well as the shape and size of each of the joining structures, can be determined based on applications in order to improve the balance between heat transfer and RF energy transfer. 3-D printing based design can also help reduce the thermal mass of the additively manufactured gas delivery nozzle. The joining structures can also have alternate profiles or structures for improved heat transfer and RF energy transfer performance. Gas zone divider wall can also be designed to provide additional zones and to improve gas flow or plasma uniformity.

In some implementations, the additive manufacturing can extend beyond the gas delivery nozzle to include other components of the source and gas delivery nozzle assembly, e.g., source and gas delivery nozzle assembly 200.

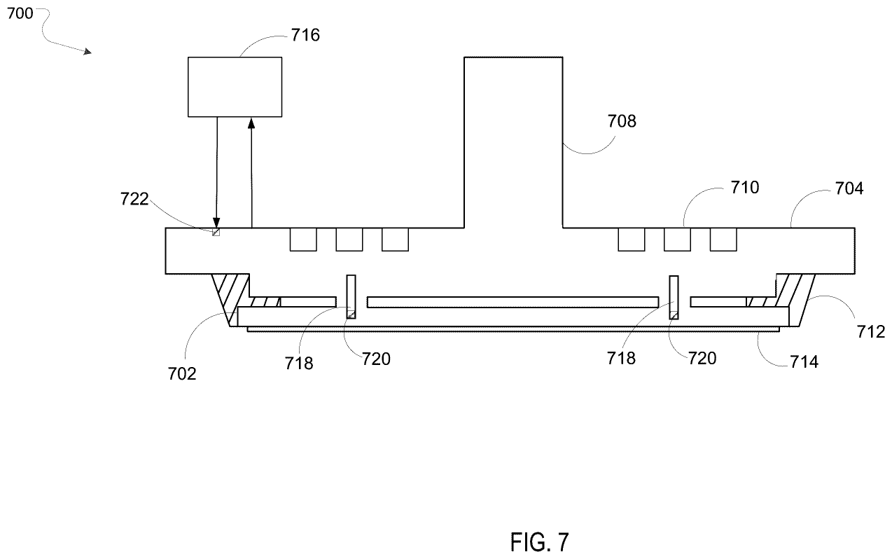

FIG. 7 illustrates an example cross sectional view of an additively manufactured source and gas delivery nozzle assembly 700 together with a chiller. As shown in FIG. 7, a gas delivery nozzle 702, chill plate 704, and RF block 708 can be formed as a single unit through additive manufacturing. A chiller 716 can be coupled to the source and gas delivery nozzle assembly 700. Although created as a single unit, the respective components 702, 704, and 708 can be similar in function to gas delivery nozzle 300, chill plate 202, and RF block 204 described above. Similarly, the chiller 716 can be similar to chiller 214 described above.

The chill plate 704 includes multiple cooling channels 710. The cooling channels 710 can be used to circulate a coolant fluid though the chill plate 704 to facilitate heat exchange. The coolant fluid can be provided by chiller 716 and coupled to the chill plate 704. The chill plate 704 can include a flow sensor 722 embedded during fabrication, for example, during additive manufacturing of source and gas delivery nozzle assembly 700. The flow sensor 722 can be positioned on the vane of the flow inlet of coolant fluid on the chill plate 704 to measure flow rate of the coolant fluid circulating through the chill plate 704. Example flow sensor 722 can include an accelerometer. The flow sensor 722 can enable tunability to modify the flow rate of the coolant fluid to chill plate 704 and tune the target temperature for gas delivery nozzle 702. The gas delivery nozzle 702 can include multiple joining structures 718 with embedded sensors 720. The embedded sensors 720 can be similar in function to sensors 316 described above. Example sensors 720 can include thermocouples to measure the temperature of gas delivery nozzle 702 at multiple places. The combination of flow sensor 722 and sensors 720 can provide a closed loop control of the temperature of gas delivery nozzle 702.

The additively manufactured combined chill plate 704, gas delivery nozzle 702, and RF block 708 can be made of a single material, for example, aluminum alloy such as aluminum 6061-T6. The additively manufactured combined chill plate 704 and gas delivery nozzle 702 can improve thermal conductivity throughout the single component of the combined chill plate and showerhead electrode base. Furthermore, by fabricating the gas delivery nozzle 702, chill plate 704, and RF block 708 through a single additive manufacturing process, alignment pins can be eliminated.

After fabrication, the source and gas delivery nozzle assembly 700 can be augmented with additional components as part of the assembly process. For example, insulator 712 can be added to provide insulation between the conductive gas delivery nozzle and other components of a processing chamber, such as a lid assembly. In another example, a gas distribution plate 714 can be affixed to the lower electrode portion of the gas delivery nozzle 702. As described above with respect to FIG. 2, the gas delivery plate provide a layer of material to protect the gas delivery nozzle from the plasma in the plasma processing chamber. Similarly, connections for gas lines, electrical power, and sensors (not shown) can be added.

In some implementations, a computer aided design (CAD) model of the combined gas delivery nozzle, chill plate, and RF block is first made and then a slicing algorithm maps the information for every layer. A layer starts off with a thin distribution of powder spread over the surface of a powder bed. A chosen binder material then selectively joins particles where the combined gas delivery nozzle, chill plate, and RF block is to be formed. Then a piston which supports the powder bed and the part-in-progress is lowered in order for the next powder layer to be formed. After each layer, the same process is repeated followed by a final heat treatment to make the combined gas delivery nozzle, chill plate, and RF block. Since 3-D printing can exercise local control over the material composition, microstructure, and surface texture, various (and previously inaccessible) geometries may be achieved with this method.

In some implementations, the combined gas delivery nozzle, chill plate, and RF block as described in this specification may be represented in a data structure readable by a computer rendering device or a computer display device. FIG. 9 is a schematic illustration of an example computing system 900 that can be used to execute implementations of the present disclosure. In some implementations, memory 920 is a computer-readable medium that may contain a data structure that represents the combined gas delivery nozzle, chill plate, and RF block. The data structure may be a computer file, and may contain information about the structures, materials, textures, physical properties, or other characteristics of one or more articles. The data structure may also contain code, such as computer executable code or device control code that engages selected functionality of a computer rendering device or a computer display device. The data structure may be stored on the computer-readable medium. The computer readable medium may include a physical storage medium such as a magnetic memory, floppy disk, or any convenient physical storage medium. The physical storage medium may be readable by the example computing system 900 to render the combined gas delivery nozzle, chill plate, and RF block represented by the data structure on a computer screen or a physical rendering device which may be an additive manufacturing device, such as a 3-D printer.

In some implementations, additive manufacturing of the combined gas delivery nozzle, chill plate, and RF block can avoid variations in manufacturing individual parts of the gas delivery nozzle, chill plate, and RF block, as well as e-beam welding, machining wastage, handling, and tooling associated with manufacturing individual parts. It can also eliminate assembly mismatch and press-fit issues and improve repeatability and chamber matching.

Although FIG. 7 illustrates the combined gas delivery nozzle, chill plate, and RF block, all three need not be formed from a single additive manufacturing process. For example, a combined gas delivery nozzle and chill plate can be formed through additive manufacturing and then coupled to a separate RF block.

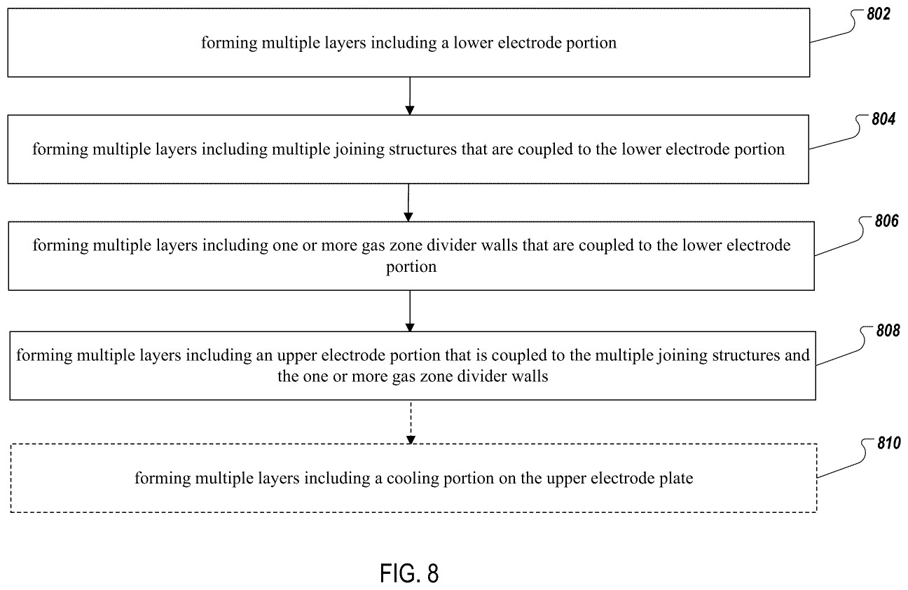

FIG. 8 illustrates a flow diagram of an example process 800 for manufacturing a unitary gas distribution nozzle assembly, for example, for use in a plasma based processing system. For convenience, the process 800 will be described with respect to an additive manufacturing system that performs at least some steps of the process.

The additive manufacturing system forms multiple layers including a lower electrode portion (802). The additive manufacturing system can receive, from a computer system, a data structure representative of the lower electrode portion, and use the data structure to form the multiple layers of the lower electrode portion.

The additive manufacturing system forms multiple layers including multiple joining structures that are coupled to the lower electrode portion (804). One or more sensors can be embedded within one or more joining structures during the forming of the multiple layers.

The additive manufacturing system forms multiple layers including one or more gas zone divider walls that are coupled to the lower electrode portion (806).

The additive manufacturing system forms multiple layers including an upper electrode portion that is coupled to the multiple joining structures and the one or more gas zone divider walls (808).

The additive manufacturing system optionally forms multiple layers including a cooling portion on the upper electrode plate (810). Forming the multiple layers of the cooling portion can include forming one or more cooling channels configured to receive a coolant fluid. One or more sensors can be embedded during the forming of the multiple layers.

The additive manufacturing system can receive, from a computer system, a data structure representative of the upper electrode portion, and use the data structure to form the multiple layers of the upper electrode portion. The upper electrode portion, the lower electrode portion, the multiple joining structures, and the one or more gas zone divider walls are of a same material. Each of the multiple joining structures is positioned between and coupled to the upper electrode portion and the lower electrode portion. Each of the multiple joining structures is configured to transfer radio-frequency energy and thermal energy between the upper electrode portion and the lower electrode portion. The one or more gas zone divider walls are positioned between and coupled to the upper electrode portion and the lower electrode portion. The one or more gas zone divider walls are configured to separate a region between the upper electrode portion and the lower electrode portion into two or more plenum chambers.

The multiple layers can be formed in a different direction. For example, the multiple layers can be formed in a reverse order in which the multiple layers forming the upper electrode portion are formed first by the additive manufacturing system. The multiple joining structures and the one or more gas zone divider walls can then be additively formed on the upper electrode portion.

FIG. 9 illustrates a schematic diagram of an example computing system 900. The system 900 can be used for the operations described in association with the implementations described herein. For example, the system 900 may be included in any or all of the computing systems discussed herein. The system 900 includes a processor 910, a memory 920, a storage device 930, and an input/output device 940. The components 910, 920, 930, and 940 are interconnected using a system bus 950. The processor 910 is capable of processing instructions for execution within the system 900. In some implementations, the processor 910 is a single-threaded processor or a multi-threaded processor. The processor 910 is capable of processing instructions stored in the memory 920 or on the storage device 930 to display graphical information for a user interface on the input/output device 940.

The memory 920 stores information within the system 900. In some implementations, the memory 920 is a computer-readable medium. The memory 920 is a volatile memory unit. The memory 920 is a non-volatile memory unit. The storage device 930 is capable of providing mass storage for the system 900. The storage device 930 is a computer-readable medium. The storage device 930 may be a floppy disk device, a hard disk device, an optical disk device, or a tape device. The input/output device 940 provides input/output operations for the system 900. The input/output device 940 includes a keyboard and/or pointing device. The input/output device 940 includes a display unit for displaying graphical user interfaces.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, it is to be understood that the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A structure embodied in a machine readable medium used in a design process, the structure comprising:
a unitary gas distribution nozzle assembly comprising:
an upper electrode portion;
a lower electrode portion;
a plurality of joining structures that join the lower electrode portion and the upper electrode portion; and
one or more gas zone divider walls; wherein:
the upper electrode portion, the lower electrode portion, the plurality of joining structures, and the one or more gas zone divider walls are of a same material;
each of the plurality of joining structures is positioned between and coupled to the upper electrode portion and the lower electrode portion;
each of the plurality of joining structures is configured to transfer radio-frequency (RF) energy and thermal energy between the upper electrode portion and the lower electrode portion;
the one or more gas zone divider walls are positioned between and coupled to the upper electrode portion and the lower electrode portion; and
the one or more gas zone divider walls are configured to separate a region between the upper electrode portion and the lower electrode portion into two or more plenum chambers.

2. The structure of claim 1, wherein the structure resides on storage medium as a data format used for an exchange of layout data.

3. The structure of claim 1, wherein the structure includes at least one of test data files, characterization data, verification data, or design specifications.

4. The structure of claim 1, wherein the same material is an electrical conductor formed from a metal or metal alloy.

5. The structure of claim 1, wherein the one or more gas zone divider walls are annular walls that demarcate at least an inner plenum chamber and an outer plenum chamber within the region between the upper electrode portion and the lower electrode portion.

6. The structure of claim 1, wherein the lower electrode portion comprises a plurality of gas output holes that couple a plenum chamber of the two or more plenum chambers to an outer surface of the lower electrode portion.

7. The structure of claim 1, wherein the unitary gas distribution nozzle assembly further comprises a cooling portion positioned above and coupled to the upper electrode portion, wherein the cooling portion is configured to provide cooling to the upper electrode portion.

8. The structure of claim 7, wherein the unitary gas distribution nozzle assembly further comprises an embedded sensor to measure a flow rate of a coolant fluid circulating the cooling portion, and wherein the coolant fluid circulates from a chiller and to the cooling portion to provide cooling to the upper electrode portion.

9. The structure of claim 7, wherein the unitary gas distribution nozzle assembly further comprises a radio-frequency block portion positioned above and coupled to the cooling portion, and wherein the radio-frequency block portion couples RF energy to gas in the two or more plenum chambers.

10. The structure of claim 1, wherein a cross-section shape of each of the plurality of joining structures comprises one of a cylindrical, angled, trapezoidal, hourglass, and rectangular shape.

11. The structure of claim 1, wherein the unitary gas distribution nozzle assembly further comprises one or more sensors embedded in one or more of the plurality of joining structures.

12. A plasma processing system, comprising:
a unitary gas distribution nozzle assembly comprising:
an upper electrode portion;
a lower electrode portion;
a plurality of joining structures that join the lower electrode portion and the upper electrode portion; and
one or more gas zone divider walls; wherein:
the upper electrode portion, the lower electrode portion, the plurality of joining structures, and the one or more gas zone divider walls are of a same material;
each of the plurality of joining structures is positioned between and coupled to the upper electrode portion and the lower electrode portion;
each of the plurality of joining structures is configured to transfer radio-frequency (RF) energy and thermal energy between the upper electrode portion and the lower electrode portion;
the one or more gas zone divider walls are positioned between and coupled to the upper electrode portion and the lower electrode portion; and
the one or more gas zone divider walls are configured to separate a region between the upper electrode portion and the lower electrode portion into two or more plenum chambers.

13. The plasma processing system of claim 12, wherein the same material is an electrical conductor formed from a metal or metal alloy.

14. The plasma processing system of claim 12, wherein the unitary gas distribution nozzle assembly further comprises a cooling portion positioned above and coupled to the upper electrode portion, wherein the cooling portion is configured to provide cooling to the upper electrode portion.

15. The plasma processing system of claim 14, wherein the unitary gas distribution nozzle assembly further comprises an embedded sensor to measure a flow rate of a coolant fluid circulating the cooling portion, and wherein the coolant fluid circulates from a chiller and to the cooling portion to provide cooling to the upper electrode portion.

16. The plasma processing system of claim 12, wherein the unitary gas distribution nozzle assembly further comprises one or more sensors embedded in one or more of the plurality of joining structures.

17. A method, comprising:
additively manufacturing a unitary gas distribution nozzle assembly, wherein additively manufacturing the unitary gas distribution nozzle assembly comprises:
forming multiple layers including a lower electrode portion;
forming multiple layers including multiple joining structures that are coupled to the lower electrode portion;
forming multiple layers including one or more gas zone divider walls that are coupled to the lower electrode portion; and
forming multiple layers including an upper electrode portion that is coupled to the multiple joining structures and the one or more gas zone divider walls; wherein:
the upper electrode portion, the lower electrode portion, the plurality of connecting structures, and the one or more gas zone divider walls are of a same material;
each of the plurality of connecting structures is positioned between and coupled to the upper electrode portion and the lower electrode portion;
each of the plurality of connecting structures is configured to transfer radio-frequency (RF) energy and thermal energy between the upper electrode portion and the lower electrode portion;
the one or more gas zone divider walls are positioned between and coupled to the upper electrode portion and the lower electrode portion; and
the one or more gas zone divider walls are configured to separate a region between the upper electrode portion and the lower electrode portion into two or more plenum chambers.

18. The method of claim 17, wherein additively manufacturing the unitary gas distribution nozzle assembly further comprises forming multiple layers including a cooling portion positioned above and coupled to the upper electrode portion, wherein the cooling portion is configured to provide cooling to the upper electrode portion.

19. The method of claim 18, wherein the unitary gas distribution nozzle assembly further comprises an embedded sensor to measure a flow rate of a coolant fluid circulating the cooling portion, and wherein the coolant fluid circulates from a chiller and to the cooling portion to provide cooling to the upper electrode portion.

20. The method of claim 17, wherein the unitary gas distribution nozzle assembly further comprises one or more sensors embedded in one or more of the plurality of joining structures.
